(19) United States
(12) Patent Application Publication
(10) Pub. No.: US 2025/0342578 A1
(43) Pub. Date: Nov. 6, 2025

(54) WAFER DETERMINATION METHOD, DETERMINATION PROGRAM, DETERMINATION APPARATUS, WAFER PRODUCTION METHOD, AND WAFER

(71) Applicant: SUMCO CORPORATION, Minato-ku, Tokyo (JP)

(72) Inventors: Marina TANIGAWA, Minato-ku, Tokyo (JP); Shuichi OMOTE, Minato-ku, Tokyo (JP)

(73) Assignee: SUMCO CORPORATION, Minato-ku, Tokyo (JP)

(21) Appl. No.: 18/862,214

(22) PCT Filed: May 2, 2023
(86) PCT No.: PCT/JP2023/017198

§ 371 Date: Nov. 1, 2024

(30) Foreign Application Priority Data
Jun. 15, 2022 (JP) 2022-096858

(51) Int. Cl. G06T 7/00; G01N 21/88; G01N 21/95

(52) U.S. Cl. CPC G06T 7/001; G01N 21/9501; G06T 7/0008; G01N 2021/8887; G06T 2207/20081; G06T 2207/30148

(57) ABSTRACT

A determination method for a wafer 30 includes: obtaining a captured image 40 of at least a portion of a wafer 30 as a determination image to be used to determine whether the wafer is acceptable or not, excluding the captured image 40 from the determination image when the captured image 40 corresponds to a misdetermination candidate image, and determining whether the wafer 30 is acceptable or not based on the determination image.

### TECHNICAL FIELD

The present disclosure relates to a wafer determination method, a determination program, a determination apparatus, a wafer production method, and a wafer.

### BACKGROUND

Conventional methods for classifying wafer defects using wafer defect images are known (see Patent Document 1, etc.).

### CITATION LIST

### Patent Literature

PTL 1: JP 2021-174980 A1

### SUMMARY

### Technical Problem

With the aim of eliminating visual inspection or reducing the man-hours involved in visual inspection, technology to automatically detect wafer defects is being considered. In such a case, when photographing the wafer to be inspected, an abnormality in the photographing apparatus may generate images that make it difficult to distinguish the wafer defects. Such images may reduce the accuracy of defect determination. By improving the accuracy of defect determination, the quality of products such as wafers or products that use wafers as materials should be improved.

Therefore, the purpose of the present disclosure is to propose a determination method, a determination program, a determination apparatus, a wafer production method, and a wafer that can improve product quality.

### Solution to Problem

One embodiment of the present disclosure that solves the above problem is as follows.

[1]

A determination method including:
obtaining a captured image of at least a portion of a wafer as a determination image to be used to determine whether the wafer is acceptable or not, excluding the captured image from the determination image when the captured image corresponds to a misdetermination candidate image, and
determining whether the wafer is acceptable or not based on the determination image.
   [2]

The determination method according to [1] above, further including determining that the captured image corresponds to the misdetermination candidate image in at least one of the following cases: when at least part of area in which the wafer 30 is captured is missing in the captured image, or when a predetermined portion of the wafer is captured in the captured image.

[3]

The determination method according to [1] above, further including generating a model to determine whether the captured image corresponds to the misdetermination candidate image, using a teacher data including the misdetermination candidate image.

[4]

A determination program that causes a processor to execute the determination method according to any one of [1] to [3] above.

[5]

A determination apparatus comprising a control unit that executes the determination method according to any one of [1] to [3] above.

[6]

A wafer production method including determining whether a wafer is acceptable or not by performing the determination method according to any one of [1] to [3] above.

[7]

A wafer that has been determined to be acceptable by performing the determination method according to any one of [1] to [3] above.

### Advantageous Effect

According to the wafer determination method, the determination program, the determination apparatus, the wafer production method, and the wafer of the present disclosure, product quality can be improved.

### BRIEF DESCRIPTION OF THE DRAWINGS

In the accompanying drawings:

FIG. 1 is a block diagram illustrating an example of the configuration of a determination system in accordance with one embodiment;

FIG. 2 is a plan view illustrating an example of the configuration of a wafer;

FIG. 3 illustrates an example of an image in which an end face of a wafer is taken in one round;

FIG. 4A is an enlarged view of the boxed enclosure A in FIG. 3;

FIG. 4B is an enlarged view of the boxed enclosure B in FIG. 3;

FIG. 4C is an enlarged view of the boxed enclosure C in FIG. 3;

FIG. 4D is an enlarged view of the boxed enclosure D in FIG. 3;

FIG. 5A provides an example of a captured image of the end face of a wafer, containing a missing area;

FIG. 5B provides an example of a captured image of a surface of a wafer, containing a missing area;

FIG. 6 provides an example of a captured image that contains the outer side of the edge of a surface of a wafer;

FIG. 7 provides an example of a captured image of the end face of a wafer, containing a notch;

FIG. 8 provides examples of images of the end face of a wafer that correspond to a misdetermination candidate image and those that do not correspond to the misdetermination candidate image;

FIG. 9 provides examples of images of the surface of a wafer that correspond to a misdetermination candidate image and those that do not correspond to the misdetermination candidate image; and

FIG. 10 is a flowchart displaying an example of a procedure of a determination method in accordance with one embodiment.

### DETAILED DESCRIPTION

### (Configuration Example of Determination System 1)

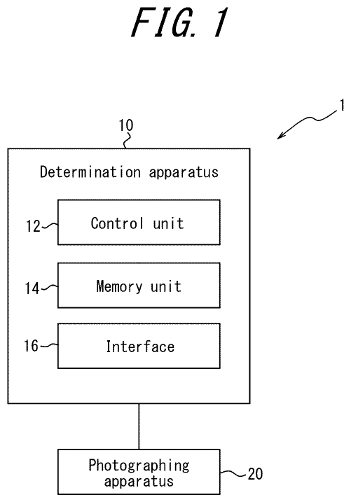

As illustrated in FIG. 1, a determination system 1 comprises a determination apparatus 10 and a photographing apparatus 20. The photographing apparatus captures an image of a wafer and other products that is used to determine whether the product is acceptable or not in the process of producing wafers and other products. The determination apparatus 10 obtains an image captured by the photographing apparatus 20 and determines whether the product is acceptable or not based on the obtained image.

The determination system 1 may determine, based on an image of product appearance, whether the product appearance meets the shipping criteria. In other words, the determination system 1 may determine whether the product appearance is acceptable or not. Not limited to the product appearance, the determination system 1 may also determine whether the internal condition of the product is acceptable or not, based on an image representing the internal condition of the product, such as an x-ray image. The determination system 1 according to this embodiment may obtain an image of appearance or internal condition of a wafer as the product and determine whether the appearance or internal condition of the wafer is acceptable or not.

### <Determination Apparatus 10>

The determination apparatus 10 comprises a control unit 12, a memory unit 14, and an interface 16.

The control unit 12 determines whether the product is acceptable or not based on an image of the product obtained from the photographing apparatus 20 by the interface 16, and outputs the result of the determination by the interface 16. The control unit 12 may include at least one processor. The processor may execute programs that implements the various functions of the control unit 12. The processor may be implemented as a single integrated circuit. The integrated circuit is also referred to as an IC. The processor may be implemented as a plurality of communicatively connected integrated circuits and discrete circuits. The processor may be implemented based on various other known technologies.

The memory unit 14 may include an electromagnetic storage medium such as a magnetic disk, or it may include a memory such as a semiconductor memory or magnetic memory. The memory unit 14 may include a non-transitory computer readable medium. The memory unit 14 stores various information such as images obtained from the photographing apparatus and programs executed by the control unit 12. The memory unit 14 may serve as a work memory for the control unit 12. At least part of the memory unit 14 may be included in the control unit 12. At least part of the memory unit 14 may be configured as a separate apparatus from the determination apparatus 10.

The interface 16 may be configured to include a communication module configured to communicate with the photographing apparatus 20 so that images can be obtained from the photographing apparatus 20. The communication module may be connected to the photographing apparatus 20 for wired or wireless communication. The communication module may be connected to the photographing apparatus 20 directly or via a communication network. The communication module may comprise a communication interface such as LAN (Local Area Network). The communication module may comprise a communication interface for contactless communication such as infrared communication or Near Field communication (NFC). The communication module may realize communication using various communication methods such as 4G (4th Generation), LTE (Long Term Evolution) or 5G (5th Generation). The communication method implemented by the communication module is not limited to the above example and may include various other methods. At least part of the communication module may be included in the control unit 12.

The interface 16 may be configured to include an output device so that the user can be notified of the results of the determination made by the control unit 12. The output device may include a display device that outputs visual information such as images, or text or graphics. The display device may be configured to include, for example, a liquid crystal display (LCD), an organic EL (electro-luminescence) display or an inorganic EL display, or a plasma display panel (PDP), etc. The display device is not limited to these displays and may be configured to include a variety of other display methods. The display device may be configured to include a light emitting device such as a Light Emitting Diode (LED) or Laser Diode (LD). The display device may be configured to include a variety of other devices. The output device may include a speaker or other devices that output sound. The output device is not limited to these examples and may include devices that can output information in various other ways.

The interface 16 may be configured to include an input device that accepts, for example, operational inputs such as start or stop of product measurement by the determination apparatus 10, or various other instruction inputs to the determination apparatus 10. The interface 16 outputs information input by the user to the control unit 12. The input device may be configured to include, for example, a touch panel or touch sensor, or a pointing device such as a mouse. The input device may be configured to include a physical key. The input device may be configured to include an audio input device such as a microphone.

### <Photographing Apparatus 20>

The photographing apparatus 20 may be configured to include a variety of cameras, such as a visible light camera, an infrared camera, or an x-ray camera. The photographing apparatus 20 may be configured to include a light source, such as a visible light source or an x-ray source, that illuminates wafers or other products to be captured.

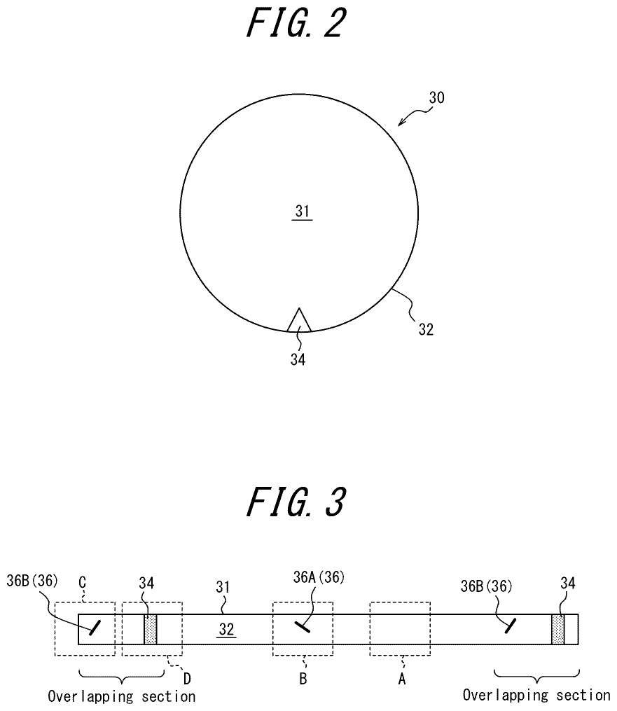

The photographing apparatus 20 is configured to capture at least part of a product, such as a wafer. When capturing a wafer 30 illustrated in FIG. 2, the photographing apparatus 20 may, for example, capture the end face 32 of the wafer 30 over one lap to generate a long image of the appearance of the end face 32 of the wafer 30, as illustrated in FIG. 3. The image of the end face 32 of the wafer 30 illustrated in FIG. 3 includes overlapping sections captured at the same location to include the entire circumference of the end face 32. In order to capture the end face 32 of the wafer 30 over a single lap, the photographing apparatus 20 may be configured so that the wafer 30 rotates with respect to a fixed camera or the camera rotate around the circumference of the wafer 30.

The wafer 30 has a defect 36 on the end face 32. The defect 36 can include a scratch or a chipping occurring on the end face 32 or the surface 31 of the wafer 30. The defect 36 can include foreign matter such as dust on the end face 32 or the surface 31 of the wafer 30. The defects 36 in the image illustrated in FIG. 3 includes a defect 36A and a defect 36B, which represent scratches.

The wafer 30 has a notch 34 as a marker indicating the direction of the crystal axis of the wafer 30. The notch 34 is formed as a cutout inward from the end face 32 of the wafer 30. The notch 34 appears as a cutout when viewed from the surface 31 of the wafer 30. The notch 34 appears recessed when viewed from the end face 32 of the wafer 30.

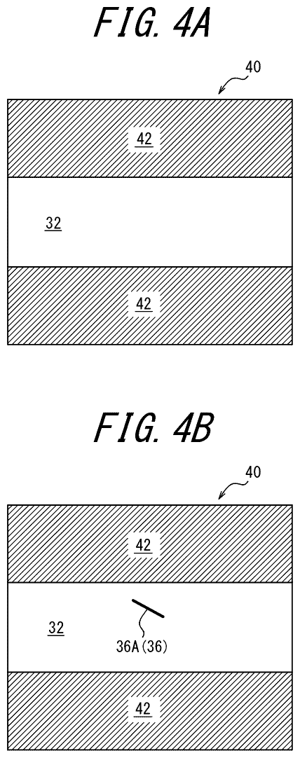

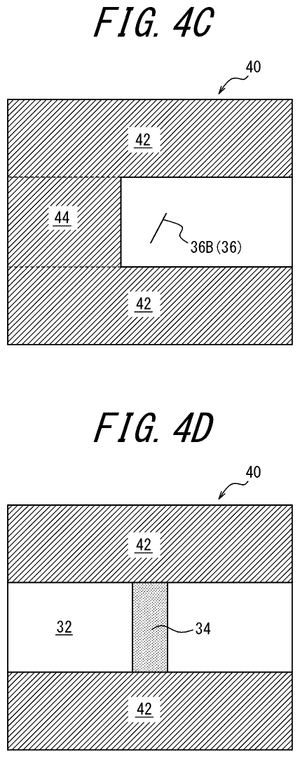

The photographing apparatus 20 may generate an image of a portion of the end face 32 cropped as illustrated in FIGS. 4A, 4B, 4C, and 4D. FIG. 4A corresponds to an enlarged image of the dashed enclosure represented by A in FIG. 3. The enlarged image in FIG. 4A contains neither a defect 36 nor a notch 34. FIG. 4B corresponds to an enlarged image of the dashed enclosure represented by B in FIG. 3. The enlarged image in FIG. 4B includes a defect 36A. FIG. 4C corresponds to an enlarged image of the dashed enclosure represented by C in FIG. 3. The enlarged image in FIG. 4C includes a defect 36B. FIG. 4D corresponds to an enlarged image of the dashed enclosure represented by D in FIG. 3. The enlarged image in FIG. 4D includes a notch 34.

The photographing apparatus 20 may generate an image of a portion of the end face 32 of the wafer 30 cropped from a long image generated by capturing the end face 32 of the wafer 30 over one lap. The photographing apparatus 20 may capture the end face 32 of the wafer 30 and generate an image of the area where a defect 36 may be included.

When photographing the surface 31 of the wafer 30, the photographing apparatus 20 may generate an image of a portion of the surface 31 of the wafer 30 cropped from the full surface image generated by capturing the surface 31 of the wafer 30 in a scanning manner. The photographing apparatus 20 may capture the surface 31 of the wafer 30 in a scanning manner and produce an image of the area where a defect 36 may be included.

As described above, the photographing apparatus 20 is configured to capture at least a portion of the wafer 30. The photographing apparatus 20 outputs an image of at least a portion of the wafer 30 to the determination apparatus 10.

### (Operation Example of Determination System 1)

In the determination system 1, the photographing apparatus 20 generates an image of at least a portion of a wafer 30 and outputs it to the determination apparatus 10. The image of at least a portion of the wafer 30 captured by the photographing apparatus 20 is also referred to as a captured image. The determination apparatus 10 obtains, by means of the interface 16, the captured image generated by the photographing apparatus 20 as an image to be determined. The image to be determined by the determination apparatus 10 is also referred to as a determination image. The control unit 12 of the determination apparatus 10 determines whether the wafer 30 is acceptable or not based on the determination image.

The captured image can include an image that contains a defect 36. On the other hand, the captured image can include an image that does not contain a defect 36. The captured image can include an image that can be erroneously determined by the control unit 12 to contain a defect 36, even though it does not contain a defect 36. If the control unit 12 uses an image, for the determination, that could be erroneously determined to contain a defect 36 even though it does not contain a defect 36, it is more likely to incorrectly determine the acceptability of the wafer 30.

Therefore, the control unit 12 excludes an image that could be erroneously determined to contain a defect 36 even though it does not contain a defect 36 from the images to be determined. The image that may be erroneously determined to contain a defect 36 even though it does not contain a defect 36 is also referred to as a misdetermination candidate image.

The control unit 12 determines whether the captured image obtained from the photographing apparatus 20 corresponds to the misdetermination candidate image. The control unit 12 uses a captured image that is determined not to correspond to the misdetermination candidate image as the determination image to determine whether the wafer 30 is acceptable or not. The control unit 12 does not use a captured image that is determined to correspond to the misdetermination candidate image as the determination image. In other words, the control unit 12 excludes, from the determination images, a captured image that is determined to correspond to the misdetermination candidate image.

The control unit 12 may generate a model for determining whether the captured image corresponds to the misdetermination candidate image. The model for determining whether the captured image corresponds to the misdetermination candidate image is also referred to as a determination model for misdetermination candidate images. The determination model for misdetermination candidate images is configured to output a determination result as to whether or not the input captured image corresponds to the misdetermination candidate image. The control unit 12 may generate a model for determining whether the wafer 30 is acceptable or not based on a determination image excluding a captured image corresponding to the misdetermination candidate image. The model for determining whether the wafer 30 is acceptable or not based on the determination image excluding the captured image corresponding to the misdetermination candidate image is also referred to as a determination model for defects 36. The determination model for defects 36 is configured to output a determination result, based on an input determination image, as to whether the wafer 30 in the determination image is acceptable or not.

The control unit 12 may use the determination model for misdetermination candidate images connected with the determination model for defects 36. The control unit 12 may input a captured image to the determination model for misdetermination candidate images and exclude a misdetermination candidate image from determination images based on the determination result output from the determination model for misdetermination candidate images. The control unit 12 may input the determination image excluding the misdetermination candidate image into the determination model for defects 36, and based on the determination result output from the determination model for defects 36, determine whether the wafer 30 in the captured image that was first input into the determination model for misdetermination candidate images is acceptable or not.

The control unit 12 may use a single model to determine whether a captured image corresponds to the misdetermination candidate image and to determine whether the wafer 30 is acceptable or not based on a determination image excluding a captured image that corresponds to the misdetermination candidate image. The single model that implements both determining misdetermination candidate images and determining the acceptability of the wafer is also referred to as a composite determination model. The control unit 12 may input a captured image to the composite determination model and determine whether the wafer 30 in the captured image input to the composite determination model is acceptable or not based on the determination result output from the composite determination model.

### <Determination of Misdetermination Candidate Images>

The determination model for misdetermination candidate images may be generated by learning using a teacher data that includes at least one of: the image that corresponds to the misdetermination candidate image or the image that does not correspond to the misdetermination candidate image. The determination model for misdetermination candidate images may be generated as a pattern matching model that identifies at least one of: the pattern that corresponds to the misdetermination candidate image or the patterns that do not corresponds to the misdetermination candidate image. The determination model for misdetermination candidate images may be generated so that various algorithms, including but not limited to these, can be used to determine the misdetermination candidate image. The control unit 12 may generate the determination model for misdetermination candidate images itself or obtain it from an external apparatus.

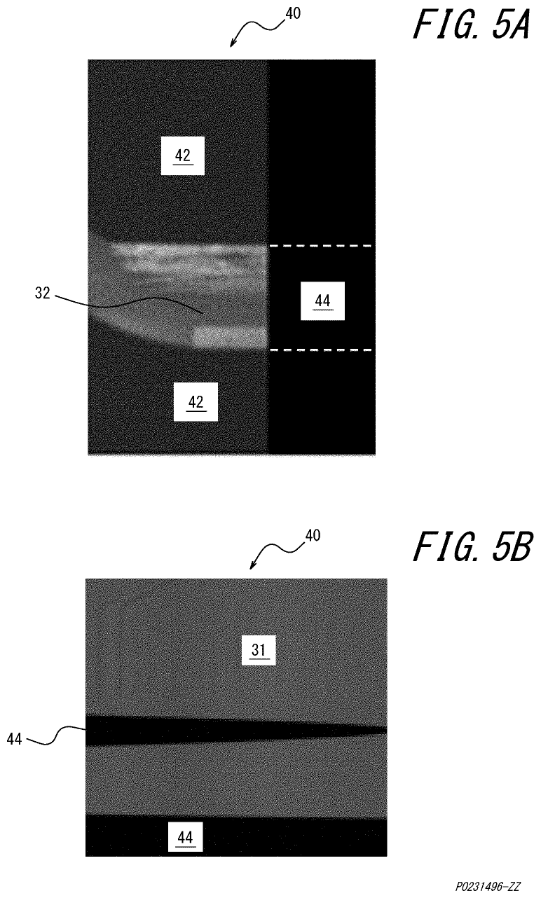

The image that corresponds to the misdetermination candidate image is as illustrated below. For example, as illustrated in FIGS. 5A and 5B, the captured image 40 that contains a missing area 44 corresponds to the misdetermination candidate image.

In the captured image 40 illustrated in FIG. 5A, the end face 32 of the wafer 30 and a background area 42, where there is no wafer 30, are captured. Suppose that the control unit 12 is configured to determine whether the wafer 30 is acceptable or not based on an image of the area of the captured image 40 in which the end face 32 is captured from the left end to the right end of the captured image 40, ignoring the background area 42. However, in the captured image 40 illustrated in FIG. 5A, the image of the area on the right side is black due to an abnormality in the photographing apparatus 20 or other causes. In other words, a portion of the image of the end face 32, which should be shown all the way to the right end, is missing. The missing area of the image of the end face 32 is represented as a missing area 44. The control unit 12 may incorrectly determine that the missing area 44 is a defect 36 if the captured image 40 illustrated in FIG. 5A is used as a determination image.

Also, in the captured image 40 illustrated in FIG. 5B, the surface 31 of the wafer 30 and a missing area 44, which is a black image, are captured. In other words, a portion of the image of the surface 31 of the wafer 30 is missing. Suppose that the control unit 12 is configured to determine whether the wafer 30 is acceptable or not based on an image in which the surface 31 of the wafer 30 is captured on the entire area of the captured image 40. However, the inner portion and the edge of the captured image 40 illustrated in FIG. 5B are black due to an abnormality in the photographing apparatus 20 or other causes. In other words, part of the image of the surface 31 is missing. The missing portion of the image of the surface 31 is represented as a missing area 44. The control unit 12 may incorrectly determine that the missing area 44 is a defect 36 if the captured image 40 illustrated in FIG. 5B is used as the determination image.

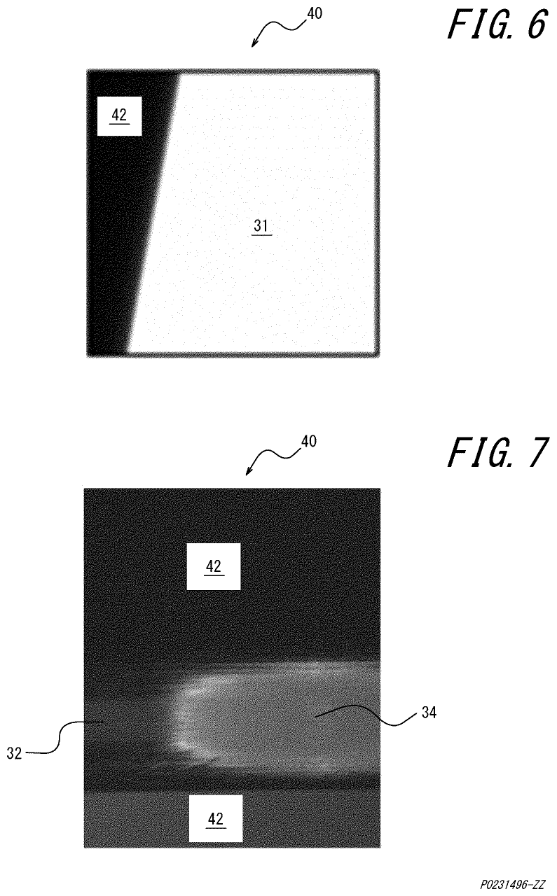

In addition, for example, in the captured image 40 illustrated in FIG. 6, the area outside the surface 31 of the wafer 30, where there is no wafer 30, is captured as a background area 42. If the control unit 12 determines whether the wafer 30 is acceptable or not based on the assumption that the surface 31 is on the entire area of the captured image 40, it may incorrectly determine the background area 42 shown in the captured image 40 illustrated in FIG. 6 as a defect 36.

In addition, for example, in the captured image 40 illustrated in FIG. 7, a notch 34 is captured in the end face 32 of the wafer 30. The control unit 12 may incorrectly determine that the notch 34 is a defect 36 if the captured image 40 illustrated in FIG. 7 is used as the determination image.

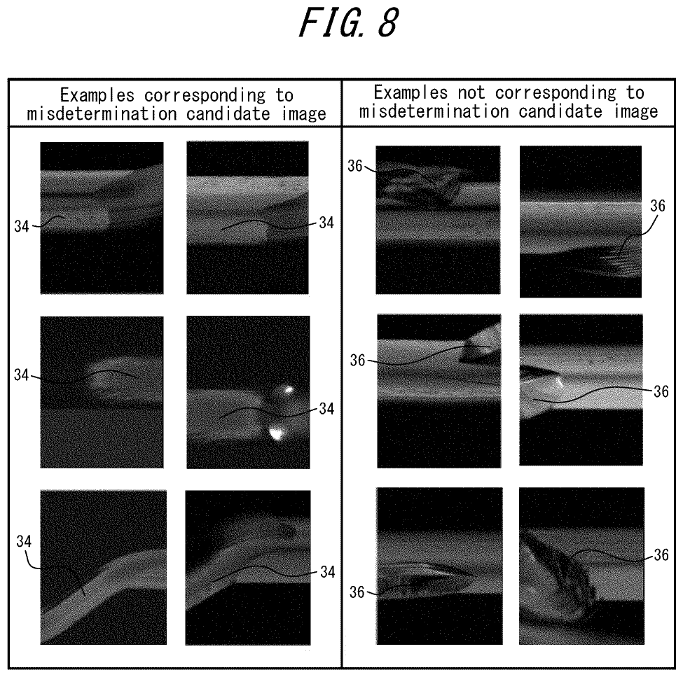

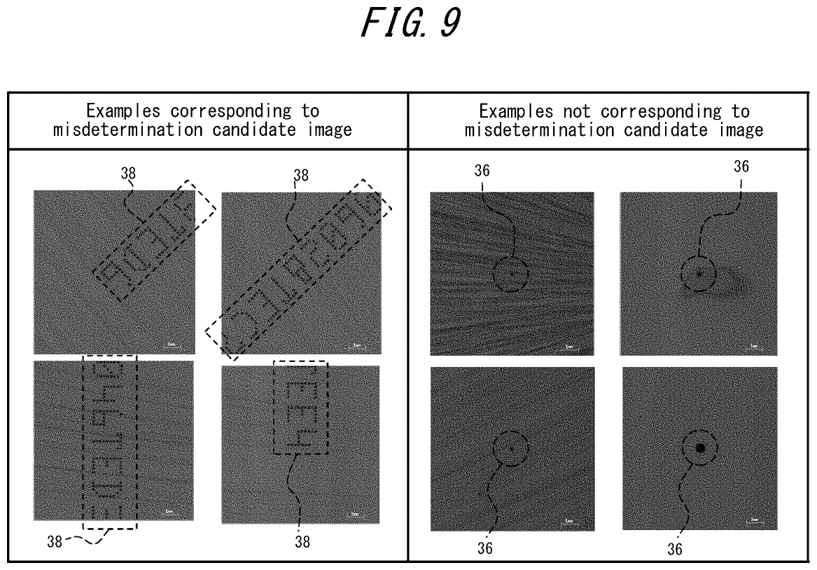

FIG. 8 also provides captured images 40 of the end face 32 of the wafer 30, classified into two categories: examples that correspond to the misdetermination candidate images and examples that do not correspond to the misdetermination candidate images. As an example of the image that corresponds to the misdetermination candidate images, images containing a notch 34 are provided. As an example of the image that does not corresponds to the misdetermination candidate images, images containing a chipping defect 36 are provided. In addition, FIG. 9 provides captured images 40 of the surface 31 of the wafer 30, classified into two categories: examples that correspond to the misdetermination candidate images and examples that do not correspond to the misdetermination candidate images. As an example of the image that corresponds to the misdetermination candidate images, images containing dots 38 which are generated by a laser marker on the surface 31 of the wafer 30 are provided. As an example of the image that does not correspond to the misdetermination candidate images, images containing a pinhole defect 36 are provided.

As discussed above, the captured images 40 can be classified according to whether or not they are misdetermination candidate images. The control unit 12 may determine that the captured image 40 is a misdetermination candidate image when at least part of the area in which the wafer 30 is captured is missing in the captured image 40. Alternatively, the control unit 12 may determine that the captured image 40 corresponds to a misdetermination candidate image when a predetermined portion, such as a notch 34 of the wafer 30 or laser marking dots 38 of the wafer 30 is captured in the captured image.

The control unit 12 may first exclude the images containing a predetermined portion such as a notch 34 or dots 38 from the captured images 40. The control unit 12 may further exclude images that contain a missing area 44 or unwanted background 42 from the captured images 40 without the predetermined portion. In other words, the determination model for misdetermination candidate images may be divided into: a determination model for an image containing a predetermined portion, and a determination model for an image containing a missing area 44 or other portion.

### <Determination of Misdetermination Candidate Images>

The control unit 12 determines the wafer 30 is acceptable or not based on the determination image showing the wafer 30. The control unit 12 may determine that the wafer 30 is acceptable if the determination image of the wafer 30 does not contain a defect 36. The control unit 12 may determine that the wafer 30 is not acceptable if the determination image of the wafer 30 contains a defect 36.

The determination model for defects 36 may be generated by training it using teacher data that includes at least one of the images containing a defect 36 or images that do not contain a defect 36. The determination model for defects 36 may be generated as a model for pattern matching that identifies at least one of the patterns that correspond to defects 36 or the patterns that do not correspond to defects 36. The determination model for defects 36 may be generated so that to determine the presence or absence of a defect 36 using various algorithms, including but not limited to these. The control unit 12 may generate the determination model for defects 36 itself, or it may obtain it from an external apparatus.

As illustrated in FIG. 8 as an example that does not correspond to the misdetermination candidate images, the defect 36 can include a chipping at the end face 32 of the wafer 30. As illustrated in FIG. 9 as an example that does not correspond to the misdetermination candidate image, the defect 36 can include a pinhole in the surface 31 of the wafer 30. The defect 36 is not limited to these examples and can include a variety of other forms such as dust or dirt on the surface 31 or the end face 32 of the wafer 30.

As described above, the control unit 12 determines whether the wafer 30 has a defect 36 based on the determination image, and determines that the wafer 30 is not acceptable if the wafer 30 has a defect 36. In other words, the control unit 12 determines whether the wafer 30 is acceptable or not based on the determination image.

When the control unit 12 determines whether the wafer 30 is acceptable or not using a composite determination model that combines the determination model for misdetermination candidate images and the determination model for defects 36, the composite determination model may be generated by the control unit 12 itself, or it may be obtained from an external apparatus. The composite determination model may be generated by training it using teacher data that includes images that correspond to the misdetermination candidate images, and images that do not correspond to the misdetermination candidate images and include or do not include a defect 36. The composite determination model may be generated as a model for pattern matching that identifies at least one of the patterns that correspond to the misdetermination candidate images, or the patterns that do not correspond to the misdetermination candidate images and include a defect 36 or do not include a defect 36.

### <Example of Flowchart of Determination Method>

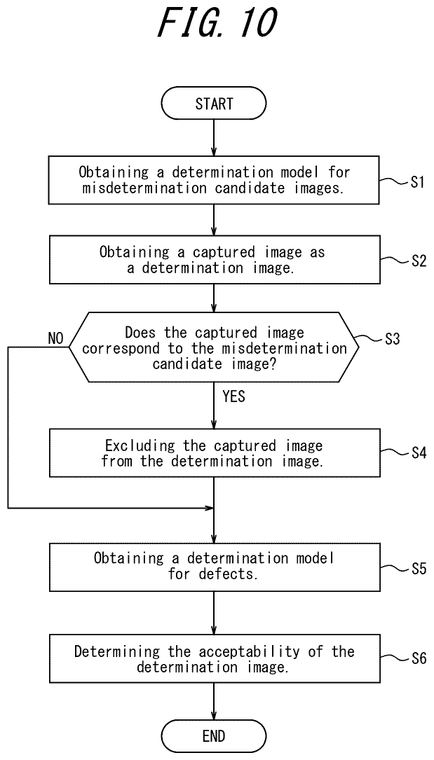

The control unit 12 of the determination apparatus 10 may determine whether the wafer 30 is acceptable or not by executing a determination method that includes the flowchart procedure illustrated in FIG. 10. The determination method may be realized as a determination program to be executed by the control unit 12.

The control unit 12 obtains a determination model for misdetermination candidate images (step S1). The control unit 12 obtains a captured image 40 as a determination image from the photographing apparatus 20 (step S2). The control unit 12 determines whether the captured image 40 corresponds to the misdetermination candidate image (step S3). If the captured image 40 does not correspond to the misdetermination candidate image (step S3: NO), the control unit 12 proceeds to step S5. If the captured image 40 corresponds to the misdetermination candidate image (step S3: YES), the control unit 12 excludes the captured image 40 from the determination image (step S4).

The control unit 12 obtains a determination model for defects 36 (step S5). The control unit 12 determines whether the determination image obtained in steps S1 through S4 is acceptable or not by applying the determination image obtained in steps S1 through S4 to the determination model for defects 36 (step S6). The control unit 12 determines that the wafer 30 in the determination image is acceptable if the determination image has been determined as acceptable, and determines that the wafer 30 in the determination image is not acceptable if the determination image has been determined as not acceptable. After the execution of the procedure in step S6, the control unit 12 terminates the execution of the procedure in the flowchart in FIG. 10.

In the example flowchart in FIG. 10, the control unit 12 separately uses a determination model for misdetermination candidate images and a determination model for defects 36, however, a composite determination model may be used.

### Examples

This example verifies the effect, in the determination system 1 according to this embodiment, of determining whether a captured image corresponds to the misdetermination candidate image in order to determine whether a wafer 30 is acceptable or not. In this example, the results of the determination as to the acceptability of wafers 30 made by humans based on captured images 40 are compared with the results of the determination as to the acceptability of the wafers made by the control unit 12 based on the captured images. The combination of the results as acceptable or not acceptable made by humans and the results as acceptable or not acceptable made by the control unit 12 can be classified into four typologies.

The combinations in which the determination made by humans and the determination made by the control unit 12 coincide are classified into the following two types. If the determination as not acceptable made by humans for a wafer 30 and the determination as not acceptable made by the control unit 12 for the wafer 30 coincide, the determination as not acceptable made by the control unit 12 for that wafer 30 is classified as a true positive (TP). Also, if the determination as acceptable made by humans for a wafer 30 and the determination as acceptable made by the control unit 12 for the wafer 30 coincide, the determination as acceptable made by the control unit 12 for that wafer 30 is classified as a true negative (TN).

The combinations in which the determination made by humans and the determination made by the control unit 12 do not coincide are classified into the following two types. If humans determine a wafer 30 as acceptable and the control unit 12 determines the wafer 30 as not acceptable, the determination as not acceptable made by the control unit 12 for that wafer 30 is classified as a false negative (FN). Conversely, if humans determine a wafer 30 as acceptable and the control unit 12 determines the wafer 30 as not acceptable, the determination as acceptable made by the control unit 12 for that wafer 30 is classified as a false positive (FP).

The determination accuracy is calculated based on the frequency of classification into each type. The value ((TP+TN)/(TP+TN+FP+FN)), obtained by dividing the sum of the number classified as true positive and the number classified as true negative by the total number of samples, is calculated as Accuracy. The Accuracy represents the percentage of correct determinations. The higher the Accuracy, the more accurate the determination.

The value (TP/(TP+FP)), obtained by dividing the number classified as true positive by the number classified as true positive and the number classified as false positive, is calculated as Precision. The Precision represents the percentage of samples that are actually “not acceptable” out of the samples that are determined as “not acceptable”. The higher the Precision, the less likely the product will be wasted.

The value (TP/(TP+FN)), obtained by dividing the number classified as true positive by the number classified as true positive and the number classified as false negative, is calculated as Recall. The Recall represents the percentage of samples that are determined as “not acceptable” out of the samples that are actually “not acceptable”. The higher the Recall, the less likely it is that the “not acceptable” products will leak out.

Table 1 provides the results of the classification into the above-mentioned four types of combinations of: the determination results when misdetermination candidate images are excluded from determination images by the control unit 12 of the determination apparatus 10, and the determination results made by humans.

TABLE 1

Determination
Results by Model

| | | | Not |
|---|---|---|---|
| | | Acceptable | Acceptable |
| Determination | Acceptable | 42437 | 1093 |
| Results | Not | 0 | 27 |
| by Humans | Acceptable | | |

The Accuracy calculated from the results provided in Table 1 was: (42437+27)/(42437+1093+27)=97.5%. The Precision was 27/(1093+27)=2.4%. The Recall was 27/27=100%.

On the other hand, as comparative examples, Table 2 provides the results of the classification into the above-mentioned four types of combinations of: the determination results when the acceptability of the wafers 30 was determined using captured images 40 as determination images without determining whether the captured images 40 correspond to the misdetermination candidate images, and the determination results made by humans.

TABLE 2

Determination
Results by Model

| | | | Not |
|---|---|---|---|
| | | Acceptable | Acceptable |
| Determination | Acceptable | 42437 | 2872 |
| Results | Not | 0 | 27 |
| by Humans | Acceptable | | |

The Accuracy calculated from the results of comparative examples provided in Table 2 was: (42437+27)/(42437+2872+27)=93.7%. The Precision was 27/(2872+27)=0.9%. The Recall was 27/27=100%.

In comparison between Table 1 and Table 2, the Accuracy and the Precision are higher when the misdetermination candidate images are excluded from the captured images 40 in order to determine the acceptability of wafers 30 in the determination system 1 according to this embodiment. Therefore, by excluding the misdetermination candidate images from the captured images 40, the accuracy of determination on the acceptability of the wafers 30 was improved.

### CONCLUSION

As described above, in the determination system 1, the determination apparatus 10, and the determination method according to the present embodiment, the misdetermination candidate images are excluded from the captured images 40 which show at least a portion of the product, such as a wafer 30, to determine whether the product is acceptable or not. In this way, a missing area 44 or background 42 that is not a defect 36 is less likely to be erroneously determined to be a defect 36. As a result, the accuracy of determination on the acceptability of the product, such as a wafer 30, can be enhanced.

A model, such as a determination model for defects 36 or a composite determination model for defects 36, may be configured to output, for example, the results of determination on whether a product, such as a wafer 30, meets the shipping criteria. When the product is a wafer 30, the model may be configured to output the results of determination on whether the wafer 30 meets the shipping criteria. In this case, the classification is the simplest: acceptable or not acceptable. The model may, for example, classify products into multiple quality grades. If the product is a wafer 30, the model may be configured to output the results of determination on whether the wafer 30 is in a grade used in device applications or a grade used in monitoring applications based on the quality of the wafer 30, for example. The quality grade may be determined based on the number or size of defects 36 or the type of defects 36.

### OTHER EMBODIMENTS

A production method of a wafer 30 can be realized that includes the steps to perform the determination method to determine the acceptability of a wafer 30 according to this embodiment. In addition, a wafer 30 can be realized that has been determined to be acceptable by performing the determination method.

Although the embodiments pertaining to the present disclosure have been described based on the drawings and examples, it should be noted that one skilled in the art can make various changes or modifications based on the present disclosure. Therefore, it should be noted that these variations or modifications are included within the scope of this disclosure. For example, the functions included in each component or step can be rearranged in a logically consistent manner, and multiple components or steps can be combined or divided into one. Although the embodiments pertaining to the present disclosure have been described with a focus on apparatus, the embodiments pertaining to the present disclosure can also be realized as a method that includes steps executed by each component of the apparatus. The embodiments pertaining to the present disclosure can also be realized as a method executed by a processor provided with the apparatus, a program, or a storage medium in which the program is recorded. It should be understood that the scope of this disclosure includes these as well.

### INDUSTRIAL APPLICABILITY

According to the embodiments in this disclosure, product quality can be improved.

### REFERENCE SIGNS LIST

1 Determination system
10 Determination apparatus (12: Control unit, 14: Memory unit, 16: Interface)
20 Photographing apparatus
30 Wafer (31: Surface, 32: End face, 34: Notch, 36, 36A, 36B: Defect, 38: Laser marking dot)
40 Captured image (42: Background area, 44: Missing area)

1. A determination method including:
obtaining a captured image of at least a portion of a wafer as a determination image to be used to determine whether the wafer is acceptable or not,
excluding the captured image from the determination image when the captured image corresponds to a misdetermination candidate image, and
determining whether the wafer is acceptable or not based on the determination image.

2. The determination method according to claim 1, further including determining that the captured image corresponds to the misdetermination candidate image in at least one of the following cases: when at least part of area in which the wafer is captured is missing in the captured image, or when a predetermined portion of the wafer is captured in the captured image.

3. The determination method according to claim 1, further including generating a model to determine whether the captured image corresponds to the misdetermination candidate image, using a teacher data including the misdetermination candidate image.

4. A non-transitory computer readable storage medium storing a determination program that causes a processor to execute the determination method according to claim 1.

5. A determination apparatus comprising a control unit that executes the determination method according claim 1.

6. A wafer production method including determining whether a wafer is acceptable or not by performing the determination method according to claim 1.

7. A wafer that has been determined to be acceptable by performing the determination method according to claim 1.
